(19) United States
(12) Patent Application Publication
(10) Pub. No.: US 2017/0365727 A1
(43) Pub. Date: Dec. 21, 2017

(54) SOLAR CELL MODULE

(71) Applicant: Panasonic Intellectual Property Management Co., Ltd., Osaka (JP)

(72) Inventors: Tasuku ISHIGURO, Osaka (JP); Akimichi MAEKAWA, Osaka (JP); Haruhisa HASHIMOTO, Osaka (JP); Masahiro IWATA, Osaka (JP); Shoji SATO, Osaka (JP); Junpei IRIKAWA, Osaka (JP)

(21) Appl. No.: 15/691,321

(22) Filed: Aug. 30, 2017

Related U.S. Application Data
(63) Continuation of application No. PCT/JP2016/001035, filed on Feb. 26, 2016.

(30) Foreign Application Priority Data
Mar. 6, 2015 (JP) 2015-045291

(51) Int. Cl. H01L 31/0236; H01L 31/048; H01L 31/0224; H01L 31/05; H01L 31/054

(52) U.S. Cl. CPC H01L 31/02366; H01L 31/0508; H01L 31/0547; H01L 31/022425; H01L 31/048

(57) ABSTRACT

A solar cell module includes: a light-diffusing member adjacent to a solar cell; a tab line disposed on front surfaces of solar cells and having a light-diffusing shape on a light-entering side; and a protective member having first and second principal surfaces. When an average distance between a front surface of the solar cell and the second principal surface is expressed as D, a refractive index of the protective member is expressed as n, and a critical angle for total reflection satisfying sin R=1/n is expressed as R, the tab line is disposed in a zone other than a zone between a position at a distance of 3.46×D from, among ends of the light-diffusing member, an end closest to the solar cell and a position at a distance of 2×D×tan R from, among the ends, an end farthest from the solar cell.

### CROSS REFERENCE TO RELATED APPLICATION

This application is a U.S. continuation application of PCT International Patent Application Number PCT/JP2016/001035 filed on Feb. 26, 2016, claiming the benefit of priority of Japanese Patent Application Number 2015-045291 filed on Mar. 6, 2015, the entire contents of which are hereby incorporated by reference.

### BACKGROUND

### 1. Technical Field

The present disclosure relates to a solar cell module.

### 2. Description of the Related Art

It is important that a solar cell module in which solar cells are two-dimensionally disposed on a plane improve light collection efficiency for sunlight on the front surfaces of the solar cells.

Patent Literature (PTL) 1 (Japanese Unexamined Patent Application Publication No. 2013-98496) discloses a configuration in which, in a solar cell module including solar cells having gap regions and being disposed on the same plane, reflecting members are disposed which reflect light incident on the gap regions to the light-receiving surfaces of the solar cells. This configuration makes it possible to effectively use sunlight with which the gap regions between the solar cells are irradiated.

### SUMMARY

In the above solar cell module, tab lines connecting solar cells in series or in parallel are disposed on the front surfaces and back surfaces of the solar cells. For this reason, with the configuration disclosed in PTL 1, a case is assumed in which when light incident on the gap regions between the solar cells is reflected by reflecting members to the front surfaces of the solar cells, part of the reflected light hits the tab lines, and the reflected light is not efficiently incident on the front surfaces of the solar cells. In other words, the disposition of the tab lines reduces a light collection degree of the reflected light from the reflecting members to the front surfaces of the solar cells.

The present disclosure has been conceived to solve the above problem, and an object of the present disclosure is to provide a solar cell module capable of highly efficiently collecting sunlight to solar cells.

In order to solve the above problem, a solar cell module according to the present disclosure includes: a plurality of solar cells two-dimensionally disposed on a light-receiving surface; a inter-connector which is disposed on front surfaces of the plurality of solar cells, electrically connects the plurality of solar cells, and has a light-diffusing shape on a surface on a light-entering side; a light-diffusing member disposed along a formation direction of the inter-connector to be adjacent to one solar cell among the plurality of solar cells in a direction parallel to the light receiving surface; and a protective member which is disposed on the light-entering side of the plurality of solar cells, the light-diffusing member, and the interconnector, and has a first principal surface and a second principal surface opposite the light-entering side of the first principal surface, wherein when an average distance of a distance between a front surface of the one solar cell and the second principal surface and a distance between the second principal surface and a front surface of the light-diffusing member adjacent to the one solar cell is expressed as D, a refractive index of the protective member is expressed as n, and a critical angle for total reflection satisfying sin R=1/n on the second principal surface is expressed as R, the inter-connector on the front surface of the one solar cell is disposed in a zone other than a zone between a position at a distance of 3.46×D from, among ends of the light-diffusing member, an end closest to the one solar cell in a direction of the one solar cell and a position at a distance of 2×D×tan R from, among the ends of the light-diffusing member, an end farthest from the one solar cell in the direction of the one solar cell.

Since the solar cell module according to the present disclosure makes it possible to cause diffused light from a light-diffusing member to highly efficiently enter a solar cell, it is possible to improve the light collection efficiency of the solar cell and increase the output of the solar cell module.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a schematic plan view of a solar cell module according to an embodiment;

FIG. 2 is a structural cross-sectional view of the solar cell module according to the embodiment, in a column direction;

FIG. 3 is a structural cross-sectional view of a light-diffusing member and its surrounding area according to the embodiment;

FIG. 4 is a structural cross-sectional view of and its surrounding area according to the embodiment;

FIG. 5 is a structural cross-sectional view of a tab line and its surrounding area according to Variation 1 of the embodiment;

FIG. 6 is a structural cross-sectional view of a solar cell module in a row direction, for describing a disposition zone of a tab line according to the embodiment;

FIG. 7A is a structural cross-sectional view illustrating a disposition relationship between a light-diffusing member and solar cells according to Variation 2 of the embodiment;

FIG. 7B is a structural cross-sectional view illustrating a disposition relationship between a light-diffusing member and solar cells according to Variation 3 of the embodiment;

FIG. 7C is a structural cross-sectional view illustrating a disposition relationship between a light-diffusing member and solar cells according to Variation 4 of the embodiment;

FIG. 8 is a plan view of a solar cell according to the embodiment;

FIG. 9 is a plan view of a solar cell according to Variation 5 of the embodiment; and

FIG. 10 is a cross-sectional view illustrating a layered structure of the solar cell according to the embodiment.

### DETAILED DESCRIPTION OF THE EMBODIMENTS

The following describes in detail a solar cell module according to an embodiment of the present disclosure with reference to the drawings. Embodiments described below each show a specific example of the present disclosure. Therefore, numerical values, shapes, materials, structural elements, the arrangement and connection of the structural elements, etc. shown in the following embodiments are mere examples, and are not intended to limit the present disclosure. Moreover, among the structural elements in the embodiments below, structural elements not recited in any one of independent claims which indicate the broadest concepts of the present disclosure are described as optional structural elements.

The figures are schematic diagrams and are not necessarily precise illustrations. In addition, in the diagrams, identical structural components are given the same reference signs.

In this DESCRIPTION, a “front surface” of a solar cell denotes a surface which more light can enter inwardly in comparison to a “back surface” which is a surface opposite the front surface. (At least 50 to 100% of light enters inwardly from the front surface.) Examples of the front surface include a surface which no light enters inwardly from a “back surface” side. In addition, a “front surface” of a solar cell module denotes a surface which light on a side opposite the “front surface” of the solar cell can enter, and a “back surface” of the solar cell module denotes a surface opposite the front surface of the solar cell module. It should be noted that, unless specifically limited, an expression such as “provide a second member on a first member” is not intended only for a case in which the first and second members are provided in direct contact with each other. In other words, examples of this expression include a case in which another member is between the first and second members. It should also be noted that regarding the expression “substantially XX,” for example, “substantially the same” is intended to include not only exactly the same but also something that can be substantially recognized as the same.

### Embodiment

### [1. Basic Configuration of Solar Cell Module]

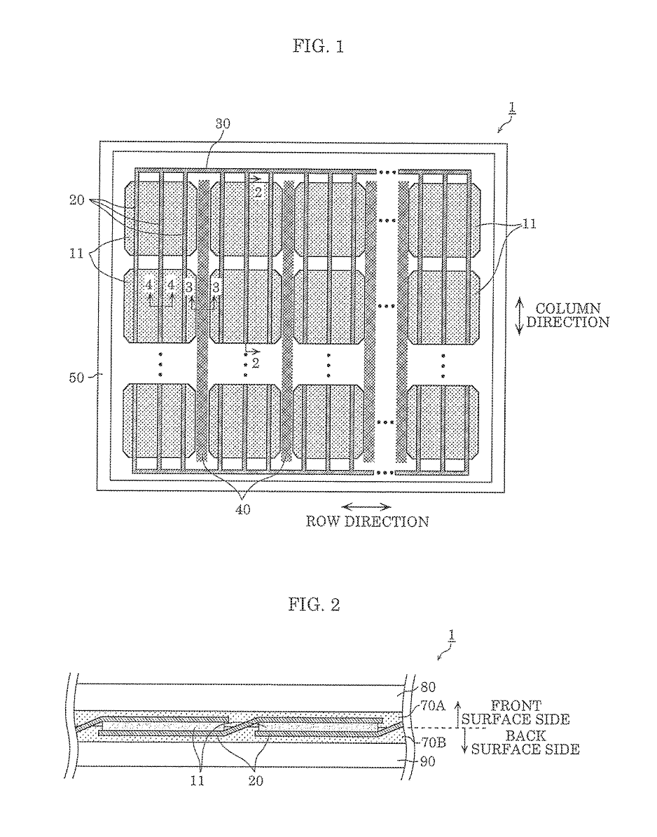

The following describes an example of the basic configuration of a solar cell module according to the embodiment, with reference to FIG. 1.

FIG. 1 is a schematic plan view of the solar cell module according to the embodiment. Solar cell module 1 illustrated in the figure includes solar cells 11, tab lines 20, connecting lines 30, light-diffusing members 40, and frame 50. It should be noted that although not shown in FIG. 1, solar cell module 1 further includes front surface encapsulant member 70A, back surface encapsulant member 70B, front surface protective member 80, and back surface protective member 90 (see FIG. 2).

Solar cells 11 are planar photovoltaic cells which are two-dimensionally disposed on a light-receiving surface and generate electric power in response to light irradiation.

Tab lines 20 are inter-connectors disposed on front surfaces of solar cells 11 and electrically connecting solar cells 11 adjacent to each other in a column direction. In addition, tab lines 20 have a light-diffusing shape on a light-entering side surface. The light-diffusing shape is a shape having a light diffusion function. The light-diffusing shape allows light having entered tab lines 20 to be diffused on the front surfaces of tab lines 20, and the diffused light to be redistributed to solar cells 11.

Connecting lines 30 electrically connect solar cell strings to each other. It should be noted that the solar cell strings each are an aggregate of solar cells 11 disposed in the column direction and connected by tab line 20. It should also be noted that the light-diffusing shape may be formed on light-entering side surfaces of connecting lines 30. This allows light having entered between solar cells 11 and frame 50 to be diffused on the front surfaces of tab lines 30, and the diffused light to be redistributed to solar cells 11.

Frame 50 is an outer frame member which covers an outer periphery of a panel on which solar cell elements 11 are two-dimensionally disposed.

Light-diffusing members 40 have at least one of a light reflection function and the light diffusion function,and are continuously disposed in the column direction, between solar cells 11 adjacent to each other in a row direction.

It should be noted that light-diffusing members 40 may be continuously disposed in the row direction, between solar cells 11 adjacent to each other in the column direction. In this case, tab lines 20 electrically connect solar cells 11 adjacent to each other in the row direction. In addition, light-diffusing members 40 may be disposed along a formation direction of tab lines 20, in gap regions between frame 50 and solar cells 11.

In other words, light-diffusing members 40 are disposed along the formation direction of tab lines 20 such that light-diffusing members 40 are adjacent to solar cells 11 in a direction parallel to the light-receiving surface.

Front surface encapsulant member 70A, back surface encapsulant member 70B, front surface protective member 80, and back surface protective member 90 will be described below with reference to FIG. 2.

### [2. Structure of Solar Cell Module]

The following describes in detail the of solar cell module 1 1.5 according to the embodiment.

FIG. 2 is a structural cross-sectional view of solar cell module 1 according to the embodiment, in the column direction. Specifically, FIG. 2 is a cross-sectional view of solar cell module 1, taken along line 2-2 in FIG. 1.

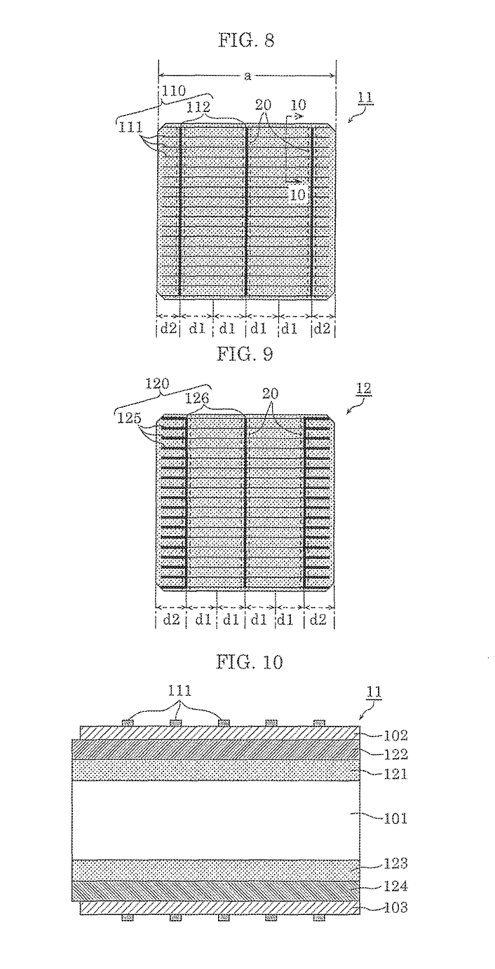

As illustrated in FIG. 2, in solar cell module 1 according to the embodiment, tab lines 20 having the light-diffusing shape are disposed on front surfaces and back surfaces of solar cells 11. In two solar cells 11 adjacent to each other in the column direction, tab line 20 disposed on the front surface of one of solar cells 11 is also disposed on the back surface of the other of solar cells 11. More specifically, an under surface of one end portion of tab line 20 is joined to bus bar electrode 112 on a front surface side of the one of solar cells 11 (see FIG. 8). Moreover, a top surface of another end portion of tab line 20 is joined to a bus bar electrode (not shown) on a back surface side of the other of solar cells 11. Consequently, a solar cell string including solar cells 11 disposed in the column direction has a configuration in which solar cells 11 are connected in series in the column direction.

Tab lines 20 and bas bar electrodes 112 (see FIG. 8) are joined by, for example, a resin adhesive. In other words, tab lines 20 are connected to solar cells 11 via the resin adhesive. The resin adhesive preferably hardens below a melting point of eutectic solder, that is, at a temperature below approximately 200° C. Examples of the resin adhesive include a thermosetting resin adhesive including acrylic resin, highly flexible polyurethane or the like, and a two-liquid reaction adhesive obtained by mixing epoxy resin, acrylic resin, or urethane resin with a curing agent. In addition, the resin adhesive may include particles having conductivity. Examples of such particles include nickel and gold-coated nickel.

Tab lines 20 may include, for example, a conductive material such as solder-coated copper foil.

Moreover, as illustrated in. FIG. 2, front surface protective member 80 is disposed on the front surface side of solar cells 11, and back surface protective member 90 is disposed on the back surface side of solar cells 11. Front surface encapsulant member 70A is disposed between a plane including solar cells 11 and front surface protective member 80, and back surface encapsulant member 70B is disposed between a plane including solar cells 11 and back surface protective member 90. Front surface protective member 80 and back surface protective member 90 are fixed by front surface encapsulant member 70A and back surface encapsulant member 70B, respectively. In other words, front surface encapsulant member 70A is disposed on the front surface side of solar cells 11, and back surface encapsulant member 70B is disposed on the back surface side of solar cells 11 and to sandwich solar cells 11 with front surface encapsulant member 70A. In addition, front surface protective member 80 is disposed to sandwich front surface encapsulant member 70A with solar cells 11, and back surface protective member 90 is disposed to sandwich back surface encapsulant member 70B with solar cells 11.

Front surface protective member 80 has a first principal surface as a light-entering side surface, and a second principal surface opposite the light-entering side surface, and is disposed on the light-entering side of solar cells 11, light-diffusing member 40, and tab lines 20 via front surface encapsulant member 70A. Front surface protective member 80 is a member for protecting the inside of solar cell module 1 from wind and rain, external shock, fire, etc., and for ensuring long-term reliability of solar cell module 1 exposed outdoors. In view of this, front surface protective member 80 may include, for example, a glass having translucency and impermeability, a film-like or plate-like hard resin, member having translucency and impermeability, or the like.

Back surface protective member 90 is a member which protects a back surface of solar cell module 1 from the external environment, and may include, for example, a resin film such as polyethylene terephthalate, or a laminated film having a structure in which Al foil is placed between resin films.

Front surface encapsulant member 70A is filled in a space between solar cells 11 and front surface protective member 80, and back surface encapsulant member 70B is filled in a space between solar cells 11 and back surface protective member 90. Front surface encapsulant member 70A and back surface encapsulant member 70B have a sealing function for shielding solar cells 11 from the external environment. The disposition of front surface encapsulant member 70A and back surface encapsulant member 70B makes it possible to ensure high heat resistance and high humidity resistance of solar cell module 1 that is to be installed outdoors.

A material of front surface encapsulant member 70A may be a polymer material having the sealing function. It should be noted that front surface encapsulant member 70A may include a polyolefin-based encapsulant as a main component. Here, examples of the polyolefin-based encapsulant include polyethylene, polypropylene, and a polymer of polyethylene and polyprophylene. Using the polyolefin-based encapsulant as front surface encapsulant member 70A makes it possible to avoid the production of acetic acid by hydrolysis of front surface encapsulant member 70A, and to reduce corrosion of solar cells 11 by acetic acid.

A material of back surface encapsulant member 70B may be a polymer material having the sealing function. It should be noted that in the light of simplification of the manufacturing process and interface adhesion with front surface encapsulant member 70A, back surface encapsulant 70B may include the same material as front surface encapsulant member 70A. In order to increase an output by taking advantage of reflection of light from back surface encapsulant member 70B, back surface encapsulant member 70B may be caused to contain white particles such as titanium oxide.

Frame 50 made of, for example, Al is attached via an adhesive to surround front surface protective member 80, back surface protective member 90, front surface encapsulant member 70A, and back surface encapsulant member 70B.

### [3. Structure of Light-Diffusing Member]

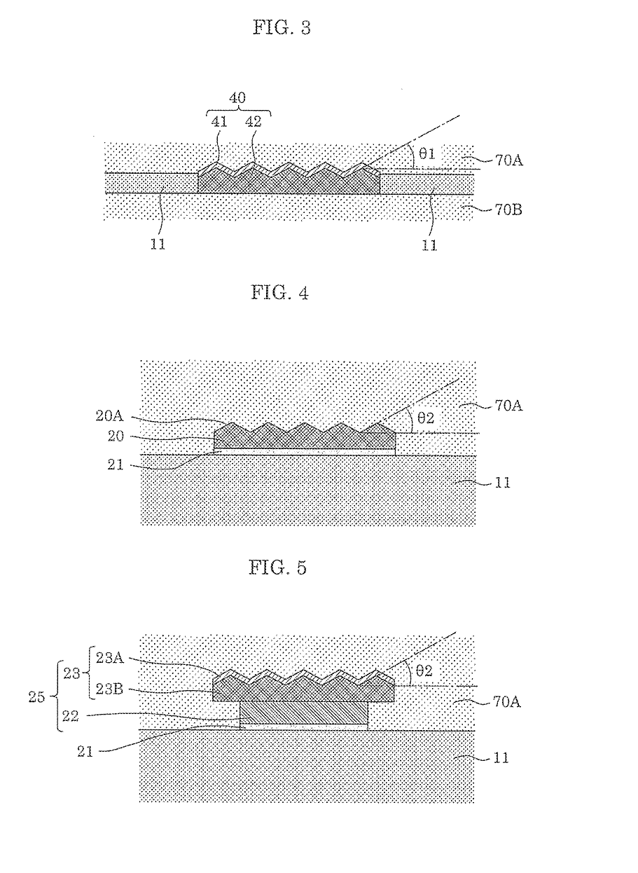

FIG. 3 is a structural cross-sectional view of a light-diffusing member and its surrounding area according to the embodiment. Specifically, FIG. 3 is a cross-sectional view of the solar cell module, taken along line 3-3 in FIG. 1, and is a cross-sectional view when a region between solar cells 11 is cut in the row direction.

As illustrated in FIG. 3, light-diffusing member 40 is disposed between adjacent solar cells 11, and a front surface of light-diffusing member 40 has an uneven shape that is continuous. This uneven shape allows light-diffusing member 40 to reflect light having entered from a substantially normal direction of a flat surface of the solar cell module, to an oblique direction. The light reflected to the oblique direction is reflected again by the second principal surface, and enters solar cell 11 adjacent to light-diffusing member 40. Light-diffusing member 40 has a thickness of, for example, 120 μm.

Light-diffusing member 40 includes, as a structure for having the uneven shape, metal layer 41 and polymer layer 42.

Polymer layer 42 has a bottom surface in contact with back surface encapsulant member 70B, and includes, as a main component, a polymer material harder than the polymer material of back surface encapsulant member 70B. It should be noted that ridges and troughs are formed in the front surface of polymer layer 42. Using the hard polymer material as the material of polymer layer 42 makes it possible to increase surface processability of polymer layer 42 and improve accuracy of the uneven shape. For example, polyethylene terephthalate (PET) is suitable for the above polymer material of polymer layer 42.

Metal layer 41 is formed on the front surface of polymer layer 42, and a surface of metal layer 41 not in contact with polymer layer 42 is in contact with front surface encapsulant member 70A. For example, Al having a high light reflectance is suitable for metal layer 41. Ridges and troughs reflecting the surface shape of polymer layer 42 are formed in metal layer 41.

With the configuration of light-diffusing member 40 illustrated in FIG. 3, the front surface of light-diffusing member 40 includes first ridges having reflecting surfaces inclined at first angle θ₁ relative to a planar direction of solar cell 11. With this, light having entered from the front surface side is reflected by each of the reflecting surfaces of the first ridges, to an oblique direction. The light reflected by each of the reflecting surfaces of the first ridges is guided by the second principal surface of front surface protective member 80 to the front surface of solar cell 11. The above surface structure of light-diffusing member 40 allows light having entered a gap region between two-dimensionally disposed solar cells 11 to be redistributed to solar cells 11, thereby improving the light collection efficiency of solar cells 11. Accordingly, it is possible to improve photoelectric conversion efficiency of the entire solar cell module.

It should be noted that although an angle range within which first angle θ₁ can fall depends on a material of light-diffusing member 40, when polymer layer 42 includes the aforementioned material, the angle range is, for example, less than or equal to 30 degrees.

Moreover, although the uneven shape of the first ridges illustrated in FIG. 3 is a regular shape, the height of ridges and troughs may be randomly determined.

Moreover, although light-diffusing member 40 illustrated in FIG. 3 includes metal layer 41, the present disclosure is not limited to this, and light-diffusing member 40 may not include metal layer 41. Even with this configuration, light-diffusing member 40 can be given the light diffusion function.

### [4. Structure of Tab Line]

FIG. 4 is a structural cross-sectional view of a tab line and its surrounding area according to the embodiment. Specifically, FIG. 4 is a cross-sectional view of solar cell module 1, taken along line 4-4 in the row direction in FIG. 1,

As illustrated in FIG. 4, tab line 20 is disposed on the front surface of solar cell 11. Tab line 20 and the front surface (bus bar electrode 112 in FIG. 8) of solar cell 11 are bonded via, for example, electrically conductive adhesive 21 by thermocompression bonding.

Examples of electrically conductive adhesive 21 include a conductive adhesive paste (SCP), a conductive adhesive film (SCF), and an anisotropic conductive film (ACF). The conductive adhesive paste is, for example, a paste adhesive produced by dispersing conductive particles into a thermosetting adhesive resin material such as an epoxy resin, an acryl resin, and a urethane resin. The conductive adhesive film and the anisotropic conductive film each are a film adhesive produced by dispersing conductive particles into a thermosetting adhesive resin material.

It should be noted that tab line 20 and solar cell 11 may be joined not by electrically conductive adhesive 21 but by a solder material. Moreover, instead of electrically conductive adhesive 21, a resin adhesive including no conductive particle may be used. In this case, tab line 20 and solar cell 11 are electrically connected by direct contact of tab line 20 and solar cell 11, by applying pressure at the time of thermocompression bonding.

Moreover, as illustrated in FIG. 4, uneven shape 20A that is continuous is formed in the front surface of tab line 20 in the embodiment. When light having entered solar cell module 1 reaches the front surface of tab line 20, uneven shape 20A scatters the light to an interface between the second principal surface of front surface protective member 80 and an environmental atmosphere. Then, the scattered light is reflected again at the interface between the second principal surface of surface protective member 80 and the environmental atmosphere, and the light is re-introduced to solar cell 11.

Accordingly, the light reflected by the front surface of tab line 20 can be effectively caused to contribute to the generation of electricity, which improves the photoelectric conversion efficiency of solar cell module 1.

Examples of tab line 20 include a line comprising copper foil whose surface has an uneven shape and is covered with a silver vapor deposited film. It should be noted that a light reflection member having a surface with an uneven shape may be deposited on a tab line having a flat surface.

With the configuration of tab line 20 illustrated in FIG. 4, the front surface of tab line 20 includes second ridges having reflecting surfaces inclined at second angle θ₂ relative to a planar direction of solar cell 11. With this, light having entered from the front surface side is reflected by each of the reflecting surfaces of the second ridges, to an oblique direction. The light reflected by each of the reflecting surfaces of the second ridges is guided by the second principal surface of front surface protective member 80 to the front surface of solar cell 11. The above surface structure of tab line 20 allows light having entered a region above tab line 20 to be redistributed to solar cells 11, thereby improving the light collection efficiency of solar cells 11. Accordingly, it is possible to improve the photoelectric conversion efficiency of the entire solar cell module.

Moreover, although the uneven shape of the second ridges illustrated in FIG. 4 is a regular shape, the height of ridges and troughs may be randomly determined.

It should be noted that the uneven shape formed on the light-entering side of tab line 20 may be formed of a member different from the conductive member included in tab line 20. The following describes a variation of the tab line having the uneven shape.

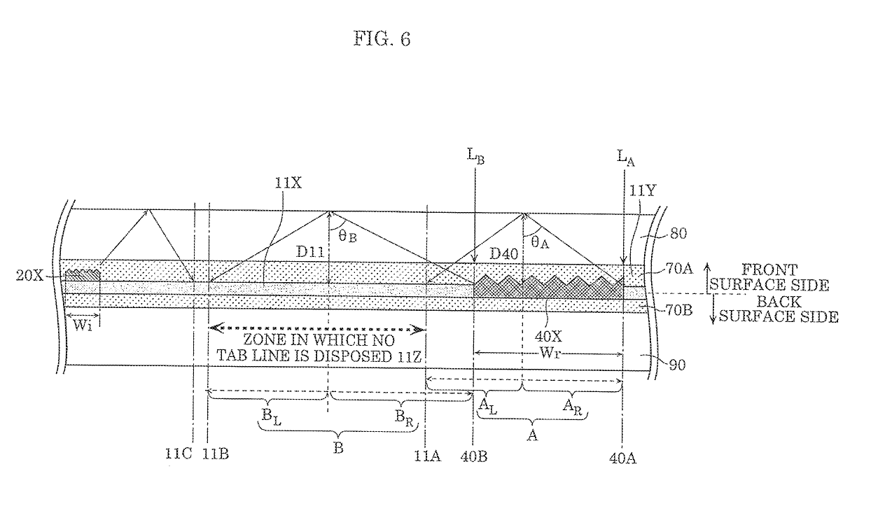

FIG. 5 is a structural cross-sectional view of a tab line and its surrounding area according to Variation 1 of the embodiment. As illustrated in FIG. 5, tab line 25 includes light-diffusing member 23 and conductive member 22, and is disposed on the front surface of solar cell 11. Tab line 25 and the front surface (bus bar electrode 112 in FIG. 8) of solar cell 11 are bonded via, for example, electrically conductive adhesive 21 by thermocompression bonding.

Light-diffusing member 23 is disposed along conductive member 22 to cover a light-entering-side surface of tab line 25. The light-entering-side surface of light-diffusing member 23 has an uneven shape that is continuous. This uneven shape allows light-diffusing member 23 to reflect light having entered from a substantially normal direction of a flat surface of the solar cell module, to an oblique direction. The light reflected to the oblique direction is reflected again by the second principal surface of front surface protective member 80, and enters solar cell 11. Light-diffusing member 23 has a thickness of, for example, 120 μm.

Light-diffusing member 23 includes, as a structure for having the uneven shape, metal layer 23A and polymer layer 23B.

Polymer layer 23B has a bottom surface in contact with conductive member 22 and front surface encapsulant member 70A, and includes, as a main component, a polymer material harder than the polymer material of front surface encapsulant member 70A. It should be noted that ridges and troughs are formed in the front surface of polymer layer 23B. Using the hard polymer material as the material of polymer layer 23B makes it possible to increase surface processability of polymer layer 23B and improve accuracy of the uneven shape. For example, polyethylene terephthalate (PET) is suitable for the above polymer material of polymer layer 23B.

Metal layer 23A is formed on the front surface of polymer layer 23B, and a surface of metal layer 23A not in contact with polymer layer 23B is in contact with front surface encapsulant member 70A. For example, Al having a high light reflectance is suitable for metal layer 23A. Ridges and troughs reflecting the surface shape of polymer layer 23B are formed in metal layer 23A.

Examples of conductive member 22 include a conductive material such as solder-coated copper foil.

With the configuration of light-diffusing member 23 illustrated in FIG. 5, the front surface of light-diffusing member 23 includes second ridges having reflecting surfaces inclined at second angle θ₂ relative to a planar direction of solar cell 11. With this, light having entered from the front surface side of light-diffusing member 23 is reflected by each of the reflecting surfaces of the second ridges, to an oblique direction. The light reflected by each of the reflecting surfaces of the second ridges is guided by the second principal surface of front surface protective member 80 to the front surface of solar cell 11. The above surface structure of light-diffusing member 23 allows light having entered a region above tab line 20 to be redistributed to solar cells 11, thereby improving the light collection efficiency of solar cells 11. Accordingly, it is possible to improve the photoelectric conversion efficiency of the entire solar cell module.

It should be noted that although an angle range within which second angle θ₂ can fall depends on a material of light-diffusing member 23, when polymer layer 23B includes the aforementioned material, the angle range is, for example, less than or equal to 30 degrees.

Moreover, although the uneven shape of the second ridges illustrated in FIG. 5 is a regular shape, the height of ridges and troughs may be randomly determined.

Moreover, although light-diffusing member 23 illustrated in FIG. 5 includes metal layer 23A, the present disclosure is not limited to this, and light-diffusing member 23 may not include metal layer 23A. Even with this configuration, light-diffusing member 23 can be given the light diffusion function.

### [5. Disposition Relationship of Inter-Connector]

The following describes a disposition relationship of tab line 20 on solar cell 11 according to the embodiment.

FIG. 6 is a structural cross-sectional view of a solar cell module in a row direction, for describing a disposition range of a tab line according to the embodiment. FIG. 6 illustrates solar cells 11X and 11Y that are adjacent to each other in the row direction, and light-diffusing member 40X disposed between solar cells 11X and 11Y. FIG. 6 further illustrates tab line 20X disposed on a front surface of solar cell 11X. Among tab lines 20 disposed on solar cell 11X, tab line 20X is a inter-connector closest to light-diffusing member 40X.

In solar cell module 1 according to the embodiment, tab line 20X is disposed in a zone other than zone 11Z illustrated in FIG. 6. Hereinafter, a disposition relationship between tab line 20X and zone 11Z will be described in detail.

First, a case will be described in which incident light L_{A} from the vertical direction of solar cell module 1 enters the front surface of solar cell 11X. Here, incident light L_{A} is light entering, among the ends of light-diffusing member 40X, end 40A that is farthest from solar cell 11X. Incident light L_{A} is reflected by a front surface of light-diffusing member 40X to an oblique direction. The reflected light is reflected by the second principal surface of front surface protective member 80 on the light-entering side, and enters the front surface of solar cell 11X.

Here, it is assumed that first angle θ₁ (deg) of the first ridges included in light-diffusing member 40 varies from θ₀ to θₘₐₓ. In this state, when first angle θ₁ (deg) satisfies the following Equation 1, position 11A (position closest to light-diffusing member 40X) is determined at which incident light L_{A} reaches farthest to the right on solar cell 11X. It should be noted that front surface encapsulant member 70A has a thickness of, for example, 0.6 mm, and front surface protective member 80 has a thickness of, for example, 3.2 mm. Moreover, front surface encapsulant member 70A has a substantially same refractive index as a refractive index of front surface protective member 80. With this relationship, the effect of front surface encapsulant member 70A can be disregarded in terms of an optical property between solar cell 11 and front surface protective member 80, and the optical property of front surface protective member 80 can be considered dominant.

$$\begin{matrix}[ Math . 1 ] & \\ sin ( 2 \times {θ}_{1} ) = sin {θ}_{A} = \frac{1}{n} & ( Equation 1 )\end{matrix}$$

Here, θ_{A} denotes an angle formed by incident light L_{A} and reflected light from light-diffusing member 40X, and B_{A} that satisfies above Equation 1 is expressed as R (deg). Moreover, n denotes the refractive index of front surface protective member 80. Specifically, R denotes a critical angle when the reflected light resulting from incident light L_{A} being reflected by end 40A is totally reflected by the second principal surface of front surface protective member 80, and an angle when incident light L_{A} reaches farthest to the right on solar cell 11X. Furthermore, when a distance between the front surface of light-diffusing member 40X and the second principal surface of front surface protective member 80 is expressed as D₄₀, and a distance between the front surface of solar cell 11X and the second principal surface is expressed as D₁₁, distance A between end 40A of light-diffusing member 40X and position 11A is expressed by the following Equation 2.

[Math. 2]

A=A_{L}+A_{R}=D₁₁ tan R+D₄₀ tan R=(D₁₁+D₄₀)tan R (Equation 2)

Moreover, when an average of D₁₁ and D₄₀ is expressed as D, Equation 2 is expressed as Equation 3.

[Math. 3]

A=2·D·tan R (Equation 3)

It should be noted that when first angle θ₁ is smaller than (90−R), θ_{A} is smaller than R, reflected light from light-diffusing member 40X penetrates the second principal surface of front surface protective member 80 to the light-entering side, and is not redistributed to the front surface of solar cell 11X.

Next, a case will be described in which incident light L_{B} from the vertical direction of solar cell module 1 enters the front surface of solar cell 11X. Here, incident; light L_{B} is light entering, among the ends of light-diffusing member 40X, end 40B closest to solar cell 11X. Incident light L_{B} is reflected by the front surface of light-diffusing member 40X to an oblique direction. The reflected light is reflected by the second principal surface of front surface protective member 80 on the light-entering side, and enters the front surface of solar cell 11X.

In this state, when first angle θ₁ (deg) is 30 degrees, position 11B (position farthest from light-diffusing member 40X) is determined at which incident light L_{B} reaches farthest to the left on solar cell 11X. When first angle θ₁ is larger than 30 degrees, an angle formed by the reflected light from the reflecting surface of the first ridge and a light-receiving surface of solar cell 11X is smaller than an angle formed by the reflecting surface and the light-receiving surface. With this relationship, the reflected light from the reflecting surface of the first ridge hits the reflecting surface of the other first ridge in the traveling direction, and does not reach the second principal surface of front surface protective member 80. For this reason, the possible maximum value of first angle θ₁ is 30 degrees. In this case, distance B between end 40B of light-diffusing member 40X and position 11B is expressed by the following Equation 4.

[Math. 4]

B=B_{L}+B_{R}=D₁₁ tan θ_{B}+D₄₀ tan θ_{B}=(D₁₁+D₄₀)tan θ_{B} (Equation 4)

Here, θ_{B} denotes an angle formed by incident light L_{B} and the reflected light from light-diffusing member 40X, and θ_{B}=(90−30)=60 degrees. Moreover, when an average of D₁₁ and D₄₀ is expressed as D, Equation 4 is expressed as Equation 5.

[Math. 5]

B=2·D·tan 60=2·D·1.73=3.46·D (Equation 5)

Specifically, tab line 20X provided on the front surface of solar cell 11X is disposed in a zone other than zone 11Z between position 11B at a distance of 3.46×D from end 40B in a direction of solar cell 11X and position 11A at a distance of 2×D×tan R from end 40A in the direction of solar cell 11X, end 40B being one of the ends of light-diffusing member 40X adjacent to solar cell 11X and closest to solar cell 11X, end 40A being another of the ends of light-diffusing member 40X and farthest from solar cell 11X.

With the configuration in which tab line 20X is disposed in the zone other than zone 11Z, the reflected light from light-diffusing member 40 is not radiated to tab line 20 on solar cell 11. Accordingly, the reflected light from light-diffusing member 40 can be caused to highly efficiently enter the front surface of solar cell 11 without being blocked by tab line 20, thereby improving the light collection efficiency of solar cell 11 and increasing the output of solar cell module 1.

Here, a specific example of zone 11Z is calculated according to Equation 1 to Equation 5. In the embodiment, when front surface protective member 80 is made of glass, the refractive index is, for example, n=1.49. At this time, critical angle R for total reflection is calculated as 42 degrees from Equation 1. Moreover, if D is a combined thickness of front surface protective member 80 and front surface encapsulant member 70A, D=3.8 mm is obtained. When R and D are substituted in Equation 3, A=6.8 mm is calculated. B is calculated as 13.2 mm from Equation 5. In the specific example, tab line 20X is disposed in a zone other than zone 11Z between position 11B at a distance of 13.2 mm from end 40B of light-diffusing member 40X and position 11A at a distance of 6.8 mm from end 40A of light-diffusing member 40X.

Moreover, tab line 20X may be disposed such that light resulting from incident light on solar cell module 1 being diffused by light-diffusing member 40X and light resulting from incident light on solar cell module 1 being diffused by tab line 20X do not overlap with each other on the front surface of solar cell 11X. Specifically, in FIG. 6, position 11C at which the light diffused by tab line 20X reaches farthest to the right is on the left (on the central side of solar 11X) relative to position 11B at which the light diffused by light-diffusing member 40X reaches farthest to the left.

With this, the light reflected by each of light-diffusing member 40X and tab line 20X and redistributed to solar cell 11X can be dispersed in the zone between tab line 20X and end 40B on solar cell 11X. Accordingly, it is possible to reduce the resistance loss of finger electrodes included in a collector electrode disposed in the above zone, thereby increasing the output of solar cell module 1.

It should be noted that although light-diffusing member 40X is disposed in contact with the lateral faces of solar cells 11X and 11Y in the above description of the disposed position of tab line 20X, solar cells 11X and 11Y and light-diffusing member 40X need not be adjacent to each other. As long as a disposition relationship between solar cells 11X and 11Y and light-diffusing member 40X allows the light reflected by each of light-diffusing member 40X and tab line 20X and redistributed to solar cell 11X to be dispersed, solar cells 11X and 11Y and light-diffusing member 40X are not limited to be adjacent to each other.

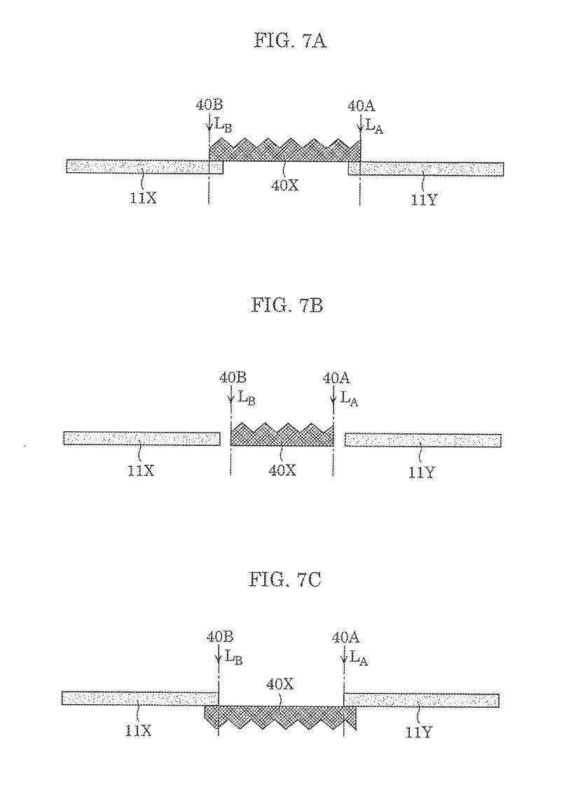

FIG. 7A is a structural cross-sectional view illustrating a disposition relationship between a light-diffusing member and solar cells according to Variation 2 of the embodiment. In the figure, light-diffusing member 40X is disposed between solar cells 11X and 11Y such that front surface ends of solar cells 11X and 11Y are in contact with back surface ends of light-diffusing member 40X. In this case, among the ends of light-diffusing member 40X, end 40A farthest from solar cell 11X is defined as an end at which incident light L_{A} can be diffused to solar cell 11X, and is the right end of light-diffusing member 40X. In contrast, among the ends of light-diffusing member 40X, end 40B closest to solar cell 11X is defined, as an end at which incident light L_{B} can be diffused to solar cell 11X, and is the left end of light-diffusing member 40X.

FIG. 7B is a structural cross-sectional view illustrating a disposition relationship between a light-diffusing member and solar cells according to Variation 3 of the embodiment. In the figure, light-diffusing member 40X is disposed between solar cells 11X and 11Y in non-contact with solar cells 11X and 11Y. In this case, among the ends of light-diffusing member 40X, end 40A farthest from solar cell 11X is defined as an end at which incident light L_{A} can be diffused to solar cell 11X, and is the right end of light-diffusing member 40X, in contrast, among the ends of light-diffusing member 40X, end 40B closest to solar cell 11X is defined as an end at which incident light L_{B} can be diffused to solar cell 11X, and is the left end of light-diffusing member 40X.

FIG. 7C is a structural cross-sectional view illustrating a disposition relationship between a light-diffusing member and solar cells according to Variation 4 of the embodiment. In the figure, light-diffusing member 40X is disposed between solar cells 11X and 11Y such that back surface ends of solar cells 11X and 11Y are in contact with front surface ends of light-diffusing member 40X. It should be noted that the first ridges are formed not on the front surface side but on the back surface side of light-diffusing member 40X according to Variation 4. In this case, among the ends of light-diffusing member 40X, end 40A farthest from solar cell 11X is defined as an end at which incident light L_{A} can be diffused to solar cell 11X, and is the left end of solar cell 11X. In contrast, among the ends of light-diffusing member 40X, end 40B closest to solar cell 11X is defined as an end at which incident light L_{B} can be diffused to solar cell 11X, and is the right end of solar cell 11X. To put it differently, when viewed from the light-entering side, ends 40A and 40B are the ends of light-diffusing member 40X that can be visually identified without being blocked by solar cells 11X and 11Y.

### [6. Configuration of Solar Cell]

The following describes a structure of each solar cell 11 which is a main component of solar cell module 1.

FIG. 8 is a plan view of a solar cell according to the embodiment. As illustrated in the figure, solar cell 11 is substantially square in a plan view. Solar cell 11 has, for example, a size of 125 mm in length×125 mm in width×200 μm in thickness. Moreover, on a surface of solar cell 11, bus bar electrodes 112 having a line shape are formed in parallel to each other, and finger electrodes 111 having a line shape are formed in parallel to each other to cross bus bar electrodes 112 at right angles. Bus bar electrodes 112 and finger electrodes 111 constitute collector electrode 110. Collector electrode 110 is formed using, for example, a conductive paste containing conductive particles such as Ag (silver). It should be noted that, for example, a line width of bus bar electrodes 112 is 1.5 mm, a line width of finger electrodes 111 is 100 μm, and a pitch of finger electrodes 111 is 2 mm. Moreover, tab lines 20 (broken lines in FIG. 8) are joined on bus bar electrodes 112.

In an example illustrated in FIG. 8, three tab lines 20 that are parallel to each other are provided on solar cell 11 to cover three bus bar electrodes 112 that are parallel to each other. Here, a distance between, among three tab lines 20, tab line 20 in the outermost part of solar cell 11 and the end of solar cell 11 closest to tab line 20 is expressed as d2. In addition, a half of a distance between tab line 20 in the outermost part of solar cell 11 and another tab line 20 inward of tab line 20 is expressed as d1. In this case, d2<d1 may hold in solar cell module 1 according to the embodiment.

When light having entered solar cell 11 is reflected by light-diffusing member 40 and redistributed to solar cell 11, the redistributed light is caused to intensively enter an end region of solar cell 11 close to light-diffusing member 40. For this reason, a current flowing through finger electrodes 111 in the end region of solar cell 11 increases, which causes the resistance loss of finger electrodes 111 in the end region to be greater than the resistance loss of finger electrodes 111 in the central region of solar cell 11.

In a conventional solar cell module whose tab lines have no uneven surface, in order to homogenize a current flowing into each tab line from finger electrodes via bus bar electrodes, the tab lines parallel to each other are disposed such that d2 is substantially equal to d1.

In contrast, in solar cell module 1 according to the embodiment, because tab lines 20 parallel to each other are disposed such that d2<d1 holds, it is possible to reduce the resistance loss of finger electrodes 111 in the end region of solar cell 11. Accordingly, it is possible to increase the output of solar cell module 1.

Moreover, second angle θ₂ (see FIG. 4) that is the inclination angle of the reflecting surfaces of the second ridges formed on tab line 20 may be smaller than first angle θ₁ that is the inclination angle of the reflecting surfaces of the first ridges included in light-diffusing member 40. With this, second angle θ₂ is relatively small, and thus a travel distance of light diffused by the front surface of tab line 20 is relatively short. Accordingly, the diffused light is caused to enter part of the front surface of solar cell 11 closer to tab line 20. In contrast, first angle θ₁ is relatively large, and thus a travel distance of light diffused by the front surface of light-diffusing member 40 is relatively long. Accordingly, the diffused light is caused to enter part of the front surface of solar cell 11 farther from light-diffusing member 40 and closer to tab line 20 of adjacent solar cell 11. In other words, the light reflected by each of light-diffusing member 40 and tab line 20 and redistributed to solar cell 11 is collected to the part closer to tab line 20. Accordingly, it is possible to reduce the resistance loss of the collector electrode when the light redistributed to solar cell 11 is collected, thereby increasing the output of solar cell module 1.

From the standpoint of reducing the resistance loss of finger electrodes 111 in the end region by the disposition of light-diffusing member 40, the following variations can be presented other than the aforementioned disposition relationship of tab lines 20 as in d2<d1.

Specifically, the collecting resistance of finger electrodes 111 formed between tab line 20 in the outermost part of solar cell 11 and the end of solar cell 11 closest to tab line 20 may be lower than the collecting resistance of finger electrodes 111 formed between two tab lines 20 disposed on solar cell 11.

FIG. 9 is a plan view of a solar cell according to Variation 5 of the embodiment. In an example illustrated in FIG. 9, an electrode width of finger electrodes 125 in an end region is greater than an electrode width of finger electrodes 125 between tab lines 20, and d2=d1. Specifically, an area occupancy ratio, viewed from a light-entering side, of finger electrodes 125 formed between tab line 20 in the outermost part of solar cell 12 and the end of solar cell 12 closest to tab line 20 is greater than an area occupancy ratio, viewed from the light-entering side, of finger electrodes 125 formed between two tab lines 20 disposed on solar cell 12. Here, the area occupancy ratio refers to a ratio of an area of finger electrodes 125 in a predetermined region viewed from a normal direction of a light-receiving surface of solar cell 12 to a power generation effective area of solar cell 12 in the predetermined region. With this, the collecting resistance of finger electrodes 125 in the end region is lower than the collecting resistance of finger electrodes 125 between tab lines 20. Accordingly, it is possible to reduce the resistance loss of finger electrodes 125 in the end region of solar cell 12, thereby increasing the output of solar cell module 1.

It should be noted that d2=d1 may not hold, and d2<d1 may hold in Variation 5. With this, in comparison to Variation 5, it is possible to further reduce the resistance loss of finger electrodes 125 in the end region of solar cell 12.

Moreover, the number of tab lines 20 formed on solar cells 11 and 12 is not limited to three, and may be two or at least four.

In the embodiment, the condition that tab line 20 disposed in the outermost part of solar cell 11 is not disposed in zone 11Z is expressed by relational expressions indicated as Equation 3 and Equation 5, using the thickness of front surface protective member 80 and front surface encapsulant member 70A and the reflection angle of the incident light in light-diffusing member 40.

In addition to this, the following describes a relationship among the cell size of solar cell 11, the number of tab lines 20, and zone 117.

First, as in the disposition relationship of tab lines 20 illustrated in FIG. 8 and FIG. 9, tab lines 20 disposed on solar cell 11 are assumed to have d1≈d2. In this case, distance d2 is maintained for each side of one tab line 20, and assuming that the number of tab lines disposed on one solar cell 11 is i, cell size a (illustrated in FIG. 8) is expressed by following Equation 6.

[Math. 6]

a=d2×(i×2) (Equation 6)

Equation 6 allows distance d2 between tab line 20 disposed in the outermost part of solar cell 11 and an end of solar cell 11 to be expressed by the following Equation 7, using number of tab lines i and cell size a.

$$\begin{matrix}[ Math . 7 ] & \\ d 2 = \frac{a}{i \times 2} & ( Equation 7 )\end{matrix}$$

Here, the condition that reflected light from light-diffusing member 40 does not reach tab line 20 is expressed by the following Equation 8 in view of distance B, distance d2, and width Wi of tab line 20 illustrated in FIG. 6.

$$\begin{matrix}[ Math . 8 ] & \\ B < d 2 - \frac{Wi}{2} & ( Equation 8 )\end{matrix}$$

When Equation 5 and Equation 7 are substituted in Equation 8, average distance D of a distance between the front surface of light-diffusing member 40 and the second principal surface of front surface protective member 80 and a distance between the front surface of solar cell 11 and the second principal surface is expressed by the following Equation 9. It should be noted that average distance D can be considered as the sum total of the thickness of front surface protective member 80 and the thickness of front surface encapsulant member 70A.

$$\begin{matrix}[ Math . 9 ] & \\ 3.46 D < \frac{1}{2} ( \frac{a}{i} - Wi ) & ( Equation 9 )\end{matrix}$$

Moreover, the condition that light reflected on light-diffusing member 40 does not reach again same light-diffusing member 40 is considered. At this time, when first angle θ₁ varies up to 30 degrees, Equation 1 to Equation 3 hold, and refractive index n of front surface protective member 80 is the refractive index (n=1.49) of standard glass, width Wr of light-diffusing member 40 is expressed by the following Equation 10.

[Math. 10]

Wr<A=1.81D (Equation 10)

Moreover, when first angle θ₁ is 30 degrees, Equation 5 allows width Wr of light-diffusing member 40 to be expressed by the following Equation 11.

[Math. 11]

Wr<B=3.46D (Equation 11)

It should be noted that critical width Wr of width Wr of light-diffusing member 40 defined by Equation 11 results from an assumption that front surface protective member 80 and front surface encapsulant member 70A have the same refractive index. In contrast, when the members each have a different refractive index, to be exact, the coefficient 3.46 of the right-hand side varies depending on a difference in refractive index.

Equation 6 to Equation 11 make it possible to calculate, when cell size a and number of tab lines i are optionally set, a distance between tab line 20 disposed in the outermost part of solar cell 11 and light-diffusing member 40 (Equation 8: d2−Wi/2), the upper limit of the total thickness of front surface protective member 80 and front surface encapsulant member 70A (Equation 9: D), the upper limit of width Wr of light-diffusing member 40 (Equation 10: consideration of variation in first angle θ₁), and the upper limit of width Wr of light-diffusing member 40 (Equation 11: first θ₁=30 degrees). Hereinafter, Table 1 and Table 2 show the above values in the case of cell size a=125 mm (square) and number of tab lines i=3, 4, 6, and the above values in the case of cell size a=156 mm (square) and number of tab lines i=3, 4, 5, respectively.

TABLE 1
Cell size a = 125 (mm), tab line width =
1 (mm), tab lines at equal intervals

| Number of tab lines i | 3 | 4 | 5 |
|---|---|---|---|
| Distance between tab line and | 20.3 | 15.1 | 12.0 |
| light-diffusing member (mm) | | | |
| Critical thickness of front surface | 5.9 | 4.4 | 3.5 |
| protective member + front surface | | | |
| encapsulant member (mm) | | | |
| Critical width of light-diffusing member | 10.6 | 7.9 | 6.3 |
| (consideration of variation: mm) | | | |
| Critical width of light-diffusing member | 20.3 | 15.1 | 12.0 |
| (30 degrees: mm) | | | |

TABLE 2
Cell size a = 156 (mm), tab line width =
1 (mm), tab lines at equal intervals

| Number of tab lines i | 3 | 4 | 5 |
|---|---|---|---|
| Distance between tab line and | 25.5 | 19.0 | 15.1 |
| light-diffusing member (mm) | | | |
| Critical thickness of front surface | 7.4 | 5.5 | 4.4 |
| protective member + front surface | | | |
| encapsulant member (mm) | | | |
| Critical width of light-diffusing member | 13.3 | 9.9 | 7.9 |
| (consideration of variation: mm) | | | |
| Critical width of light-diffusing member | 25.5 | 19.0 | 15.1 |
| (30 degrees: mm) | | | |

It should be noted that even when number of tab lines i is greater than or equal to six, Equation 6 to Equation 11 make it possible to calculate the above parameters.

First, by setting cell size a and number of tab lines i, each parameter shown in the tables can be determined from Table 1 and Table 2. Alternatively, first, by setting cell size a and the total thickness of the front surface protective member and the front encapsulant member, number of tab lines i and each parameter shown in the tables can be determined.

In the embodiment, it has been described that tab line 20 disposed in the outermost part of solar cell 11 is disposed in the zone other than zone 11Z between position 11B at the distance of 3.46×D from end 40B and position 11A at the distance of 2×D×tan R from end 40A. Zone 11Z between position 11B and position 11A, however, may be placed between adjacent tab lines 20, beyond tab line 20 disposed in the outermost part. With this also, light reflected by light-diffusing member 40 can be caused to highly efficiently enter the front surface of solar cell 11 without being caused to enter tab line 20, thereby improving the light collection efficiency of solar cell 11 and increasing the output of solar cell module 1. In this regard, however, when first angle θ₁ of light-diffusing member 40 varies up to 30 degrees, it is difficult to determine a condition under which zone 11Z is placed between adjacent tab lines 20. In contrast, when first angle θ₁ of light-diffusing member 40 is a predetermined angle and does not vary, from the same standpoint of Equation 6 to Equation 11, it is possible to set a condition under which zone 11Z is placed between adjacent tab lines 20.

FIG. 10 is a cross-sectional view illustrating a layered structure of the solar cell according to the embodiment. It should be noted that the figure is a cross-sectional view of solar cell 11, taken along line 10-10 in FIG. 8. As illustrated in FIG. 10, i-type amorphous silicon film 121 and p-type amorphous silicon film 122 are formed on a principal surface of n-type monocrystalline silicon wafer 101 in listed order. N-type monocrystalline silicon wafer 101, i-type amorphous silicon film 121, and p-type amorphous silicon film 122 constitute a photoelectric conversion layer, and n-type monocrystalline silicon wafer 101 serves as a main power generation layer. Moreover, light-receiving surface electrode 102 is formed on p-type amorphous silicon film 122. As illustrated in FIG. 8 and FIG. 9, collector electrode 110 including bus bar electrodes 112 and finger electrodes 111 is formed on light-receiving surface electrode 102. It should be noted that, of collector electrode 110, only finger electrodes 111 are illustrated in FIG. 10.

Moreover, i-type amorphous silicon film 123 and n-type amorphous silicon film 124 are formed on a back surface of n-type monocrystalline silicon wafer 101 in listed order. Furthermore, light-receiving surface electrode 103 is formed on n-type amorphous silicon film 124, and collector electrode 110 including bus bar electrodes 112 and finger electrodes 111 is formed on light-receiving surface electrode 103.

It should be noted that p-type amorphous silicon film 122 and n-type amorphous silicon film 124 may be formed on the back surface side of n-type monocrystalline silicon wafer 101 and a light-receiving surface side of n-type monocrystalline silicon wafer 101, respectively.

Collector electrode 110 can be formed by, for example, a printing method such as screen printing, using a thermosetting resin conductive paste which contains resin material as a binder and conductive particles such as silver particles functioning as a filler.

To improve p-n junction characteristics, solar cell 11 according to the embodiment has a structure in which i-type amorphous silicon film 121 is provided between n-type monocrystalline silicon wafer 101 and p-type amorphous silicon film 122 or n-type amorphous silicon film 124.

In solar cell 11 according to the embodiment, light-receiving surface electrode 102 on the front surface side of n-type monocrystalline silicon wafer 101 and light-receiving electrode 103 on the back surface side of n-type monocrystalline silicon wafer 101 serve as light-receiving surfaces. Charge carriers generated in n-type monocrystalline silicon wafer 101 diffuse as photocurrent into light-receiving surface electrodes 102 and 103 on the front and hack surface sides, and are collected by collector electrode 110.

Light-receiving surface electrodes 102 and 103 each are a transparent electrode including, for example, ITO (indium tin oxide), SnO₂ (tin oxide), or ZnO (zinc oxide). It should be noted that when light is caused to enter only from a side of light-receiving surface electrode 102 on the front surface side, light-receiving surface electrode 103 on the back surface side may be a non-transparent metal electrode.

It should be noted that, instead of collector electrode 110, an electrode formed on the entire area of light-receiving surface electrode 103 may be used as a collector electrode on the back surface side.

It should be noted that although the embodiment has described the configuration of reducing the resistance loss of finger electrodes 111 disposed on the front surface side of solar cell 11, it is also possible to increase the output of solar cell module 1 by reducing the resistance loss of finger electrodes 111 on the back surface side of solar cell 11. Specifically, an area occupancy ratio, viewed from the back surface side, of finger electrodes 125 formed between tab line 20 disposed in the outermost part of solar cell 12 and the end of solar cell 12 closest to tab line 20 is greater than an area occupancy ratio, viewed from the back surface side, of finger electrodes 125 formed between two tab lines 20 disposed on solar cell 12. With this, the collecting resistance of finger electrodes 125 in the end region on the back surface side of the solar cell is lower than the collecting resistance of finger electrodes 125 between tab lines 20 on the back surface side of the solar cell. Accordingly, it is possible to reduce the resistance loss of finger electrodes 125 in the end region on the back surface side of the solar cell, thereby improving the light collection efficiency without increasing an amount of light prevented from entering the back surface of solar cell 11. As a result, it is possible to increase the output of solar cell module 1.

### [7. Advantageous Effects Etc.]

Solar cell module 1 according to the embodiment includes: solar cells 11 two-dimensionally disposed on a light-receiving surface; tab line 20 which is disposed on front surfaces of solar cells 11, electrically connects solar cells 11, and has a light-diffusing shape on a surface on a light-entering side; light-diffusing member 40 disposed along a formation direction of tab line 20 to be adjacent to solar cell 11 among solar cells 11 in a direction parallel to the light-receiving surface; and protective member 80 which is disposed on the light-entering side of solar cells 11, light-diffusing member 40, and tab line 20, and has a first principal surface and a second principal surface opposite the light-entering side of the first principal surface. In solar cell module 1, when an average distance of a distance between a front surface of solar cell 11X and the second principal surface and a distance between the second principal surface and a front surface of light-diffusing member 40X adjacent to solar cell 11X is expressed as D, a refractive index of protective member 80 is expressed as n, and a critical angle for total reflection satisfying sin R=1/n on the second principal surface is expressed as R, tab line 20X on the front surface of solar cell 11X is disposed in a zone other than a zone between a position at a distance of 3.46×D from, among ends of light-diffusing member 40X, an end closest to solar cell 11X in a direction of solar cell 11X and a position at a distance of 2×D×tan R from, among the ends of light-diffusing member 40X, an end farthest from solar cell 11X in the direction of solar cell 11X.

According to the above configuration, tab line 20 on solar cell 11 is not irradiated with diffused light from light-diffusing member 40. Accordingly, light from light-diffusing member 40 can be caused to highly efficiently enter the front surface of solar cell 11, thereby improving the light collection efficiency of solar cell 11 and increasing the output of solar cell module 1.

Moreover, a front surface of light-diffusing member 40 may include a first ridge having a reflecting surface and inclined at first angle θ1 relative to a planar direction of solar cell 11, and a front surface of tab line 20 may include a second ridge having a reflecting surface and inclined at second angle θ2 relative to the planar direction of solar cell 11, second angle θ2 being less than first angle θ1.

With this, in comparison to light diffused by the front surface of light-diffusing member 40 and redistributed to solar cell 11, light diffused by the front surface of tab line 20 and redistributed to solar cell 11 is collected more closer to tab line 20. Accordingly, it is possible to reduce resistance loss when the light diffused by the front surface of tab line 20 and redistributed to solar cell 11 is collected, thereby increasing the output of solar cell module 1.

Moreover, tab line 20 on the front surface of solar cell 11 may be disposed such that light resulting from incident light on solar cell module 1 being reflected by light-diffusing member 40 and light resulting from the incident light being diffused by tab line 20 do not overlap with each other on the front surface of solar cell 11.

With this, it is possible to disperse the light reflected by each of light-diffusing member 40 and tab line 20 and redistributed to solar cell 11, in a zone between tab line 20 and end 40B on solar cell 11. Accordingly, it is possible to reduce the resistance loss of finger electrodes 111 which are a collector electrode disposed in the above zone, thereby increasing the output of solar cell module 1.

Moreover, solar cell 11 may include at least two tab lines 20 parallel to each other, and a distance between, among at least two tab lines 20, tab line 20 in an outermost part of solar cell 11 and an end of solar cell 11 which is parallel and closest to tab line ay be less than a half of a distance between tab line 20 in the outermost part and, among at least two tab lines 20, tab line 20 inward of tab line 20 in the outermost part.

With this, it is possible to reduce the resistance loss of finger electrodes 111 in an end region of solar cell 11. As a result, it is possible to increase the output of solar cell module 1.

Moreover, solar cell 11 may include tab lines 20, finger electrodes 111 crossing tab lines 20 and parallel to each other in a planar direction may be disposed on the front surface of solar cell 11, and collecting resistance of, among finger electrodes 111, finger electrodes 111 between tab line 20 in the outermost part of solar cell 11 and the end of solar cell 11 closest to tab line 20 in the outermost part may be less than collecting resistance of, among finger electrodes 111, finger electrodes 111 between two of tab lines 20 on solar cell 11.

Moreover, an area occupancy ratio, viewed from the light-entering side, of finger electrodes 111 disposed between tab line 20 disposed in the outermost part of solar cell 11 and the end of solar cell 11 closest to tab line 20 may be greater than an area occupancy ratio, viewed from the light-entering side, of finger electrodes ill disposed between two tab lines 20 on solar cell 11.

With this, the collecting resistance of finger electrodes 111 in the end region is lower than the collecting resistance of finger electrodes 111 between tab lines 20. Accordingly, it is possible to reduce the resistance loss of finger electrodes 111 in the end region of solar cell 12, thereby increasing the output of solar cell module 1.

Moreover, solar cell 11 may include i tab lines 20 disposed in parallel to each other and at equal intervals, and when a length (cell size) in a direction orthogonal to i tab lines 20 of solar cell 11 is expressed as a and a line width of i tab lines 20 is expressed as Wi, solar cell module 1 may satisfy a relationship represented by Equation 9.

This allows a calculation of a relationship among the following: cell size a and number of tab lines i; a distance between tab line in the outermost part of solar cell 11 and light-diffusing member 40 (Equation 8: d2−Wi/2); the upper limit of the total thickness of front surface protective member 80 and front surface encapsulant member 70A (Equation 9: D); the upper limit of width Wr of light-diffusing member 40 (Equation 10: consideration of variation in first angle θ1); and the upper limit of width Wr of light-diffusing member 40 (Equation 11: first angle θ1=30 degrees). As a result, for example, by setting cell size a and number of tab lines i, each of the above parameters can be determined. Alternatively, first, by setting cell size a and the total thickness of the front surface protective member and the front encapsulant member, number of tab lines i and each of the above parameters can be determined.

Moreover, ridges and troughs may be disposed in the front surface of light-diffusing member 40 or tab line 20.

With this, light having been prevented from entering solar cells 11 by tab line 20 and light having entered between adjacent solar cells 11 are diffused by the front surfaces of tab line 20 and light-diffusing member 40, respectively. Consequently, light not directly entering solar cells 11 can be redistributed to solar cells 11, and thus it is possible to increase a total photoelectric conversion efficiency of solar cell module 1.

Moreover, light-diffusing member 40 or tab line 20 may include: a polymer layer including a polymer material as a main component; and a metal layer disposed on the polymer layer.

With this, light having been prevented from entering solar cells 11 by tab line 20 and light having entered between adjacent solar cells 11 are diffused by a front surface of the metal layer. Consequently, light not directly entering solar cells 11 can be redistributed to solar cells 11, and thus it is possible to increase the total photoelectric conversion efficiency of solar cell module 1.

### (Others)

The solar cell module according to the present disclosure has been described based on the aforementioned embodiment, but the present disclosure is not limited to the embodiment.

For example, solar cell 11 may have a function as photovoltaic power in the aforementioned embodiment, and is not limited to the structure of the solar cell.

Although solar cell module 1 according to the aforementioned embodiment has the configuration in which solar cells 11 are disposed in the matrix on the plane, solar cell module 1 is not limited to the matrix disposition. For example, solar cell module 1 may have a configuration in which solar cells 11 are disposed annularly, linearly, or curve linearly.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

As an embodiment different from the aforementioned embodiment, a solar cell module is provided which does not have the configuration of solar cell module 1 illustrated in FIG. 6 but has the configuration of solar cell module 1 illustrated in FIG. 8 or FIG. 9.

In other words, in the solar cell module according to the embodiment different from the aforementioned embodiment, at least two tab lines 20 that are parallel to each other are disposed on solar cell 11, a distance between, among at least two tab lines 20, tab line 20 disposed in the outermost part of solar cell 11 and an end of solar cell 11 parallel and closest to tab line 20 is less than a half of a distance between tab line 20 disposed in the outermost part and another tab line 20 disposed inward of tab line 20.

Here, tab line 20X formed on the front surface of solar cell 11X may not he disposed in the zone other than zone 11Z between position 11B at the distance of 3.46×D from end 40B in the direction of solar cell 11X and position 11A at the distance 2×D×tan R from end 40A in the direction of solar cell 11X.

Moreover, the collecting resistance of finger electrodes 111 formed between tab line 20 disposed in the outermost part of solar cell 11 and the end of solar cell 11 closest to tab line 20 may be less than the collecting resistance of finger electrodes 111 formed between two tab lines 20 disposed on solar cell 11.

Moreover, an area occupancy ratio, viewed from the light-entering side, of finger electrodes 111 formed between tab line 20 disposed in the outermost part of solar cell 11 and the end of solar cell 11 closest to tab line 20 may be greater than an area occupancy ratio, viewed from the light-entering side, of finger electrodes 111 formed between two tab lines 20 disposed on solar cell 111.

With these, it is possible to reduce the resistance loss of finger electrodes 111 in the end region of solar cell 11. As a result, it is possible to increase the output of solar cell module 1.

What is claimed is:

1. A solar cell module, comprising:
a plurality of solar cells two-dimensionally disposed on a light-receiving surface;
a inter-connector which is disposed on front surfaces of the plurality of solar cells, electrically connects the plurality of solar cells, and has a light-diffusing shape on a surface on a light-entering side;
a light-diffusing member disposed along a formation direction of the inter-connector to be adjacent to one solar cell among the plurality of solar cells in a direction parallel to the light-receiving surface; and
a protective member which is disposed on the light-entering side of the plurality of solar cells, the light-diffusing member, and the inter-connector, and has a first principal surface and a second principal surface opposite the light-entering side of the first principal surface,
wherein when an average distance of a distance between a front surface of the one solar cell and the second principal surface and a distance between the second principal surface and a front surface of the light-diffusing member adjacent to the one solar cell is expressed as D, a refractive index of the protective member is expressed as n, and a critical angle for total reflection satisfying sin R=1/n on the second principal surface is expressed as R,
the inter-connector on the front surface of the one solar cell is disposed in a zone other than a zone between a position at a distance of 3.46×D from, among ends of the light-diffusing member, an end closest to the one solar cell in a direction of the one solar cell and a position at a distance of 2×D×tan R from, among the ends of the light-diffusing member, an end farthest from the one solar cell in the direction of the one solar cell.

2. The solar cell module according to claim 1,
wherein a first ridge having a reflecting surface is disposed on the front surface of the light-diffusing member, the reflecting surface being inclined at a first angle relative to the direction parallel to the light-receiving surface, and
a second ridge having a reflecting surface is disposed on a surface of the inter-connector on the light-entering side, the reflecting surface being inclined at a second angle relative to the direction parallel to the light-receiving surface, the second angle being less than the first angle.

3. The solar cell module according to claim 1,
wherein the inter-connector on the front surface of the one solar cell is disposed such that light resulting from incident light on the solar cell module being diffused by the light-diffusing member and light resulting from the incident light being diffused by the inter-connector do not overlap with each other on the front surface of the one solar cell.

4. The solar cell module according to claim 1,
wherein the inter-connector comprises at least two inter-connectors parallel to each other on the one solar cell, the at least two inter connectors including a first inter-connector in an outermost part of the one solar cell and a second inter-connector inward of the first inter-connector, and
a distance between the first inter-connector and an end of the one solar cell which is parallel and closest to the first interconnector is less than a half of a distance between the first inter-connector and the second inter-connector.

5. The solar cell module according to claim 1,
wherein the inter-connector comprises a plurality of inter-connectors on the one solar cell, the plurality of inter-connectors including a first inter-connector in an outermost part of the one solar cell and a second inter-connector inward of the first inter-connector,
a plurality of finger electrodes which cross the plurality of inter-connectors and are parallel to each other are disposed on the front surface of the one solar cell, and
collecting resistance of first finger electrodes disposed between the first inter-connector disposed and an end of the one solar cell, closest to the first inter-connector is less than collecting resistance of second finger electrodes disposed between two of the plurality of inter-connectors on the one solar cell, the first and second finger electrodes being included in the plurality of finger electrodes.

6. The solar cell module according to claim 5,
wherein an area occupancy ratio, viewed from the light-entering side, of the first finger electrodes disposed between the first inter-connector and the end of the one solar cell closest to the first inter-connector is greater than an area occupancy ratio, viewed from the light-entering side, of the second finger electrodes disposed between the two of the plurality of inter-connectors on the one solar cell.

7. The solar cell module according to claim 1,
wherein i inter-connectors are disposed in parallel to each other and at equal intervals on the one solar cell, each of the i inter-connectors being the inter-connector, i being an integer greater than or equal to 2, and
when a length in a direction orthogonal to the i inter-connectors of the one solar cell is expressed as a, and a line width of the i inter-connectors is expressed as WI, the solar cell module satisfies a relationship represented by:
$$\begin{matrix}[ Math . 1 ] & \\ 3.46 D < \frac{1}{2} ( \frac{a}{i} - Wi ) & \end{matrix}$$

8. The solar cell module according to claim 1,
wherein ridges and troughs are disposed in a front surface of the light-diffusing member or the inter-connector.

9. The solar cell module according to claim 1,
wherein the light-diffusing member or the inter-connector includes:
a polymer layer including a polymer material as a main component; and
a metal layer disposed on the polymer layer.
